(19) United States
(12) Patent Application Publication
(10) Pub. No.: US 2022/0220339 A1
(43) Pub. Date: Jul. 14, 2022

(54) POLISHING COMPOSITION, METHOD FOR MANUFACTURING POLISHING COMPOSITION, AND POLISHING METHOD

(71) Applicant: FUJIMI INCORPORATED, Kiyosu-shi (JP)

(72) Inventors: Daiki ITO, Kiyosu-shi (JP); Toshio SHINODA, Kiyosu-shi (JP)

(73) Assignee: FUJIMI INCORPORATED, Kiyosu-shi (JP)

(21) Appl. No.: 17/568,827

(22) Filed: Jan. 5, 2022

(30) Foreign Application Priority Data
Jan. 8, 2021 (JP) 2021-002204

(51) Int. Cl. C09G 1/02; B24B 37/04; C09K 3/14

(52) U.S. Cl. CPC C09G 1/02; C09K 3/1436; B24B 37/044

(57) ABSTRACT

There are provided a polishing composition capable of improving the polishing removal rate of a TEOS film, a method for manufacturing the polishing composition, and a polishing method.

A polishing composition contains cationized colloidal silica chemically surface-modified with an amino silane coupling agent and an anionic surfactant, in which the pH value is larger than 3 and smaller than 6.

### TECHNICAL FIELD

The present invention relates to a polishing composition, a method for manufacturing the polishing composition, and a polishing method

### BACKGROUND ART

In recent years, with the multilayer wiring on the surface of a semiconductor substrate, a so-called chemical mechanical polishing (CMP) technology of polishing and flattening a semiconductor substrate is utilized in manufacturing a semiconductor device. The CMP is a method for flattening the surface of objects to be polished (polishing targets), such as a semiconductor substrate, using a polishing composition (slurry) containing abrasives of silica, alumina, and ceria, an anticorrosive agent, and a surfactant. The objects to be polished (polishing targets) are wiring and plugs containing silicon, polysilicon, a silicon oxide film (silicon oxide), silicon nitride, metal, and the like.

Various proposals have been made so far with respect to the polishing composition to be used in polishing the semiconductor substrate by the CMP.

For example, PTL 1 describes “polishing an object to be polished containing at least a first layer containing polysilicon or modified polysilicon and a second layer containing at least one selected from the group consisting of silicon oxide, silicon nitride, silicon carbide, silicon carbonitride, silicon oxycarbide, and silicon oxynitride using a polishing liquid containing colloidal silica particles having a positive ζ potential and an anionic surfactant and having a pH value ranging from 1.5 to 7.0. PTL 1 discloses that the colloidal silica particles exhibit a positive ζ potential by the adsorption of a cationic compound to the surface of colloidal silica having a negative charge.

### CITATION LIST

### Patent Literature

PTL 1: JP 2011-216582 A

### SUMMARY OF INVENTION

### Technical Problem

Conventional polishing compositions have had room for improvement with respect to the polishing removal rate of particularly a silicon dioxide film formed using tetraethoxysilane ((Si(OC₂H₅)₄)) (hereinafter, TEOS film) among the objects to be polished.

The present invention has been made in view of such circumstances. It is an object of the present invention to provide a polishing composition capable of improving the polishing removal rate of the TEOS film, a method for manufacturing the polishing composition, and a polishing method.

### Solution to Problem

The present inventors proceeded with intensive studies in view of the above-described problem. As a result, the present inventors have found that the polishing removal rate of the TEOS film is increased (improved) using a polishing composition containing cationized colloidal silica chemically surface-modified with an amino silane coupling agent and an anionic surfactant, in which the pH value is larger than 3 and smaller than 6, and thus have completed the present invention.

### Advantageous Effects of Invention

The present invention can provide a polishing composition capable of improving the polishing removal rate of the TEOS film, a method for manufacturing the polishing composition, and a polishing method.

### DESCRIPTION OF EMBODIMENTS

Embodiments of the present invention will now be described in detail. A polishing composition of this embodiment contains cationized colloidal silica chemically surface-modified with an amino silane coupling agent and an anionic surfactant, in which the pH value is larger than 3 and smaller than 6.

The polishing composition is suitable for an application to polish objects to be polished, such as simple substance silicon, a silicon compound, and metal, e.g., an application to polish the surfaces containing simple substance silicon, polysilicon, a silicon compound, metal, and the like which are semiconductor substrates in a semiconductor device manufacturing process. The polishing composition is particularly suitable for an application to polish a silicon dioxide film formed using tetraethoxysilane (Si(OC₂H₅)₄), i.e., TEOS film. When the polishing is performed using the polishing composition, particularly the TEOS film can be polished at a high polishing removal rate.

Hereinafter, the polishing composition of this embodiment is described in detail.

### <Abrasives>

### (Type of Abrasives)

The polishing composition according to the embodiment of the present invention contains colloidal silica as abrasives. Methods for manufacturing the colloidal silica include a sodium silicate method and a sol-gel method. Colloidal silica manufactured by any manufacturing method may be used, but colloidal silica manufactured by the sol-gel method is preferable from the viewpoint of reducing metal impurities. The colloidal silica manufactured by the sol-gel method is preferable because the content of metal impurities or corrosive ions, such as chloride ions, having the property of diffusing in semiconductors is low. The manufacturing of the colloidal silica by the sol-gel method can be performed using conventional known methods. Specifically, the colloidal silica can be obtained by performing a hydrolysis/condensation reaction using a hydrolyzable silicon compound (e.g., alkoxysilane or a derivative thereof) as a raw material.

### (Surface Modification)

The colloidal silica is surface-modified by chemical treatment with an amino silane coupling agent. In this specification, the surface modification by the chemical treatment is also referred to as chemical surface modification. By the chemical surface modification, an amino group is immobilized on the surface of the colloidal silica, so that the surface of the colloidal silica is cationized. The immobilization is not physical adsorption but a chemical bond. In this specification, the colloidal silica subjected to the cationization is referred to as “cationized colloidal silica”.

A method for manufacturing colloidal silica having an amino group includes a method for immobilizing a silane coupling agent having an amino group, such as aminoethyltrimethoxysilane, on the surfaces of silica particles as described in JP 2005-162533 A. In this specification, the silane coupling agent having an amino group is referred to as an “amino silane coupling agent”.

The amino silane coupling agent includes, for example, 3-aminopropyltrimethoxysilane, 3-aminopropyltriethoxysilane (APTES), 4-amino-3,3-dimethylbutyltriethoxysilane, N-methylaminopropyltrimethoxysilane, (N,N-dimethyl-3-aminopropyl)trimethoxysilane, 2-(4-pyridylethyl)triethoxysilane, N-(2-aminoethyl)-3-aminopropyltrimethoxysilane, N-(2-aminoethyl)-3-aminopropylsilanetriol, 3-trimethoxysilyl propyldiethyldiethylenetriamine, N,N′-BIS[(3-trimethoxysilyl)propyl]ethylenediamine, [3-(1-piperazinyl)propyl]methyldimethoxysilane, N-2-(aminoethyl)-3-aminopropylmethyldimethoxysilane, 3-triethoxysilyl-N-(1,3-dimethyl-butylidene)propylamine, N-phenyl-3-aminopropyltrimethoxysilane, N-(vinylbenzyl)-2-aminoethyl-3-aminopropyltrimethoxysilane hydrochloride, N-(1,3-dimethylbutylidene)-3-(triethoxysilyl)-1-propaneamine, bis[3-(trimethoxysilyl)propyl]amine, and the like.

As the amino silane coupling agent, aminotrialkoxysilane having the structure shown in Formula (1) below is usable, for example. In Formula (1), X is an alkyl group having the number of carbon (C) atoms is 1 or more and 10 or less (hereinafter indicated as C1 to C10, the same applies in the following description), an aminoalkyl group containing 1 or more nitrogen atoms (C1 to C10), or a single bond. R1, R2, and R3 each independently represent an alkyl group (C1 to C3), hydrogen (H), or a salt thereof. The salt is, for example, hydrochloride.

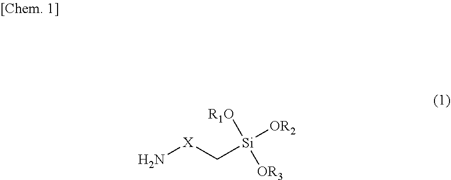

The above-described aminotrialkoxysilane includes 3-aminopropyltrimethoxysilane, 3-aminopropyltriethoxysilane (APTES), 4-amino-3,3-dimethylbutyltriethoxysilane, N-methylaminopropyltrimethoxysilane, (N,N-dimethyl-3-aminopropyl)trimethoxysilane, N-(2-aminoethyl)-3-aminopropyltrimethoxysilane, N-(2-aminoethyl)-3-aminopropylsilanetriol, 3-trimethoxysilyl propyldiethyldiethylenetriamine, and the like.

Among the amino silane coupling agents mentioned above, 3-aminopropyltriethoxysilane (APTES) has the structure shown in Formula (2). When 3-aminopropyltriethoxysilane is used as the amino silane coupling agent, an aminopropyl group is immobilized on the surface of colloidal silica, so that the surface of colloidal silica is cationized.

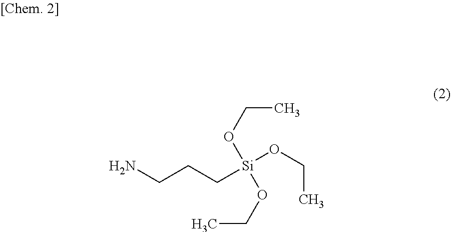

The zeta (ζ) potential of the cationized colloidal silica chemically surface-modified with the amino silane coupling agent is preferably 10 mV or more, more preferably 20 mV or more, and still more preferably 30 mV or more under acidic conditions. From the viewpoint of stably obtaining the positive zeta potential, the aminotrialkoxysilanes mentioned above are preferably used as the amino silane coupling agent, and among the aminotrialkoxysilanes, APTES is preferably used.

The amino silane coupling agent forms a chemical bond with colloidal silica, e.g., Si—O—Si bond, by a hydrolysis reaction and a dehydration condensation reaction in the chemical treatment. The zeta potential of the cationized colloidal silica chemically surface-modified with the amino silane coupling agent described above has a large positive value as compared with that of an unmodified colloidal silica under acidic conditions. Thus, the effects of the present invention can be easily obtained.

Normal colloidal silica has a zeta potential value close to zero under acidic conditions, and therefore, particles of the colloidal silica do not electrically repel each other, and thus are likely to aggregate under acidic conditions. In contrast thereto, particles of the cationized colloidal silica strongly repel each other and are satisfactorily dispersed, and thus are less likely to aggregate even under acidic conditions. As a result, the storage stability of the polishing composition is improved.

### (Aspect Ratio)

The aspect ratio of the cationized colloidal silica chemically surface-modified is preferably 1.0 or more, more preferably 1.02 or more, still more preferably 1.05 or more, and yet still more preferably 1.10 or more from the viewpoint of the polishing removal rate. The aspect ratio of the cationized colloidal silica chemically surface-modified is preferably less than 1.4, more preferably 1.3 or less, and still more preferably 1.25 or less. Thus, the surface roughness of the objects to be polished due to the shape of the abrasives can be improved. Further, the occurrence of defects due to the shape of the abrasives can be suppressed. The aspect ratio is the average value of values obtained by dividing the length of the long side of the smallest rectangle circumscribing the colloidal silica particle by the length of the short side of the same rectangle and can be obtained using common image analysis software from an image of the colloidal silica particle obtained by a scanning electron microscope.

### (Average Primary Particle Diameter)

The average primary particle diameter of the cationized colloidal silica chemically surface-modified is preferably 100 nm or less, more preferably 70 nm or less, still more preferably 50 nm or less, yet still more preferably 40 nm or less, and even yet still more preferably 35 nm or less. Further, the average primary particle diameter of the cationized colloidal silica chemically surface-modified is preferably 5 nm or more, more preferably 10 nm or more, still more preferably 20 nm or more, and yet still more preferably 25 nm. In such ranges, the polishing removal rate of the objects to be polished by the polishing composition is improved. In addition thereto, the occurrence of dishing on the surface of the objects to be polished after polishing using the polishing composition can be further suppressed. The average primary particle diameter of the colloidal silica is calculated based on the specific surface area of the colloidal silica measured by the BET method, for example.

### (Average Secondary Particle Diameter)

The average secondary particle diameter of the cationized colloidal silica chemically surface-modified is preferably 200 nm or less, more preferably 150 nm or less, still more preferably 100 nm or less, yet still more preferably 80 nm or less, and even yet still more preferably 75 nm or less. The average secondary particle diameter of the cationized colloidal silica chemically surface-modified is preferably 30 nm or more, more preferably 50 nm or more, still more preferably 60 nm or more, and yet still more preferably 65 nm or more. In such ranges, the polishing removal rate of the objects to be polished by the polishing composition is improved. In addition thereto, the occurrence of surface defects on the surface of the objects to be polished after polishing using the polishing composition can be further suppressed. Secondary particles refer to particles formed by the association of colloidal silica (primary particles), on the surface of which organic acid is immobilized, in the polishing composition. The average secondary particle diameter of the secondary particles can be measured by a dynamic light scattering method, for example.

### (Particle Size Distribution)

In the particle size distribution of the cationized colloidal silica chemically surface-modified, the ratio D90/D10 of the particle diameter D90 when the cumulative particle mass from the fine particle side reaches 90% of the total particle mass to the particle diameter D10 when the cumulative particle mass from the fine particle side reaches 10% of the total particle mass is preferably 1.5 or more, more preferably 1.8 or more, and still more preferably 2.0 or more. The ratio D90/D10 is preferably 5.0 or less and more preferably 3.0 or less. In such ranges, the polishing removal rate of the objects to be polished is improved. In addition thereto, the occurrence of surface defects on the surface of the objects to be polished after the polishing using the polishing composition can be further suppressed. The particle size distribution of the cationized colloidal silica chemically surface-modified can be obtained by a laser diffraction scattering method, for example.

### (Content)

The content of the cationized colloidal silica chemically surface-modified in the entire polishing composition is preferably 0.005% by mass or more, more preferably 0.05% by mass or more, still more preferably 0.5% by mass or more, and still more preferably 0.75% by mass or more. The content of the cationized colloidal silica chemically surface-modified in the entire polishing composition is preferably 10% by mass or less, more preferably 5% by mass or less, still more preferably 3% by mass or less, yet still more preferably 2% by mass or less, and even yet still more preferably 1.5% by mass or less. In such ranges, the polishing removal rate of the objects to be polished is improved.

The content of the cationized colloidal silica chemically surface-modified in the entire polishing composition is preferably 50% by mass or less, more preferably 30% by mass or less, and sill more preferably 20% by mass or less. In such ranges, the cost of the polishing composition can be reduced. In addition thereto, the occurrence of surface defects on the surface of the objects to be polished after the polishing using the polishing composition can be further suppressed.

### <Anionic Surfactant>

The polishing composition according to the embodiment of the present invention contains an anionic surfactant. As the anionic surfactant, anionic surfactants having one or more functional groups selected from a sulfuric acid group, a sulfonic acid group, and a phosphoric acid group are preferable. The anionic surfactants include organic acids having these functional groups or salts thereof. Such anionic surfactants include, for example, Na dodecyl sulfate, Na linear alkylbenzene sulfonate, hexadecylmethyl(3-sulfopropyl)hydroxide inner salt, Na 1-dodecane sulfonate, Na bis-(2-ethylhexyl)sulfosuccinate, branched chain alkylbenzene sulfonate, alkylnaphthalene sulfonate (butyl group), polyoxyethylene alkyl phenyl ether phosphate amine salt, polyoxyethylene styrenated phenyl ether phosphoric acid ester, ethyl acid phosphate, butyl acid phosphate, butoxyethyl acid phosphate, and the like. The anionic surfactants can be used in combination with nonionic surfactants insofar as the effects of the present invention are not impaired.

For example, among the anionic surfactants mentioned above, Na linear alkylbenzene sulfonate has the structure shown in Formula (3). In Formula (3), R represents a linear alkyl group. The number of carbon (C) atoms in the linear alkyl group is, for example, 10 or more and 16 or less.

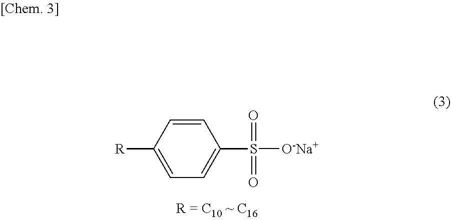

When the anionic surfactant is adsorbed on the surface of the TEOS film which is the object to be polished, the surface of the TEOS film is anionized by the functional group. Further, the zeta (ζ) potential of the cationized colloidal silica chemically surface-modified has a positive value under acidic conditions as described above. Therefore, the cationized colloidal silica, which are abrasives, is attracted to the TEOS film, which is the object to be polished, by electrostatic force under acidic conditions. This improves the polishing removal rate of the TEOS film.

### <Liquid Medium>

The polishing composition according to the embodiment of the present invention contains a liquid medium. The liquid medium functions as a dispersion medium or a solvent for dispersing or dissolving each component of the polishing composition (the cationized colloidal silica chemically surface-modified, the anionic surfactants, and additives, such as pH adjusters). The liquid medium includes water and organic solvents. One type of the liquid media can be used alone or two or more types thereof can be used as a mixture. The liquid media preferably contain water. However, from the viewpoint of preventing the inhibition of the action of each component, water containing as little impurities as possible is preferably used. Specifically, pure water or ultrapure water obtained by removing impurity ions with an ion exchange resin, and then removing contaminants through a filter or distilled water is preferable.

### <pH Adjuster>

The polishing composition according to the embodiment of the present invention has a pH value of larger than 3 and smaller than 6. A more preferable range of the pH value is 3.5 or more and 5 or less. The pH value is still more preferably 4 or less and yet still more preferably less than 4. Further, when the pH of the polishing composition is low, the zeta M potential of the cationized colloidal silica chemically surface-modified is likely to have a positive value. This is advantageous for improving the polishing removal rate of the TEOS film. On the other hand, as the pH falls below the lower limit described above, the zeta potential of the TEOS film, which is the object to be polished, changes from a negative value to zero or a positive value. Therefore, when the pH is lower than the lower limit, the interaction between the cationized colloidal silica and the TEOS film is lowered, resulting in a reduction in the polishing removal rate of the TEOS film. Hence, when the pH of the polishing composition is in the ranges above, the polishing removal rate of the TEOS film is easily improved. To achieve the pH values described above, the polishing composition may contain a pH adjuster.

The pH value of the polishing composition can be adjusted by adding the pH regulator. As the pH adjuster, acids, bases, or both may be used or inorganic compounds, organic compounds, or both may be used.

Specific examples of the acids as the pH adjuster include inorganic acids or organic acids. Specific examples of the inorganic acids include sulfuric acid, nitric acid, boric acid, carbonic acid, hypophosphorous acid, phosphorous acid, phosphoric acid, and the like. As the pH adjuster, the inorganic acids are preferably used. Among the inorganic acids, sulfuric acid and nitric acid are more preferable and nitric acid is particularly preferable. The organic acids include carboxylic acids and organic sulfuric acids. Specific examples of the carboxylic acids include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, butyric acid, citric acid, lactic, acid, and the like. Specific examples of the organic sulfuric acids include methanesulfonic acid, ethanesulfonic acid, isethionic acid, and the like. One type of these acids may be used alone or two or more types thereof may be used in combination. When SiN is contained in the object to be polished, the polishing removal rate of the SiN can be improved by using phosphoric acid-based inorganic acids or carboxylic acid-based or phosphoric acid-based organic acids. These acids may be contained as the pH adjuster in the polishing composition, may be contained as an additive for improving the polishing removal rate, or may be contained as both the pH adjuster and the additive in combination.

Specific examples of the bases as the pH adjuster include alkali metal hydroxides or salts thereof, alkaline earth metal hydroxides or salts thereof, quaternary ammonium hydroxides or salts thereof, ammonia, amines, and the like. Specific examples of the alkali metals include potassium, sodium, and the like. Specific examples of the alkaline earth metals include calcium, strontium, and the like. Specific examples of the salts include carbonates, hydrogen carbonates, sulfates, acetates, and the like. Specific examples of the quaternary ammonium include tetramethylammonium, tetraethylammonium, tetrabutylammonium, and the like.

The quaternary ammonium hydroxide compound includes quaternary ammonium hydroxides or salts thereof. Specific examples thereof include tetramethylammonium hydroxide, tetraethylammonium hydroxide, tetrabutylammonium hydroxide, and the like. Specific examples of the amines include methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, anhydrous piperazine, piperazine hexahydrate, 1-(2-aminoethyl)piperazine, N-methylpiperazine, guanidine, and the like.

One type of these bases may be used alone or two or more types thereof may be used in combination. Among these bases, ammonia, ammonium salts, alkali metal hydroxides, alkali metal salts, quaternary ammonium hydroxide compounds, and amines are preferable, and ammonia, potassium compounds, sodium hydroxides, quaternary ammonium hydroxide compounds, ammonium hydrogen carbonates, ammonium carbonates, sodium hydrogen carbonates, and sodium carbonates are more preferable. The polishing composition more preferably contains potassium compounds as the base from the viewpoint of preventing metal contamination. The potassium compounds include potassium hydroxides or potassium salts, and specific examples thereof include potassium hydroxide, potassium carbonate, potassium hydrogen carbonate, potassium sulfate, potassium acetate, potassium chloride, and the like.

Further, a case where a buffer pH adjuster, which is a mixture of an acid and a salt of the acid, is used as the pH adjuster is preferable because the pH does not vary in polishing the TEOS. A combination of the acid and the salt of the acid includes a combination of acids, such as acetic acids and lactic acids, and salts, such as ammonium salts, sodium salts, and potassium salts of the acids. From the viewpoint of impurities, ammonium salts are particularly preferably used.

### <Water-Soluble Polymer>

The polishing composition according to the embodiment of the present invention may contain a water-soluble polymer. When the objects to be polished contain polysilicon, the addition of a water-soluble polymer to the polishing composition enables the adjustment of the polishing removal rate, e.g., increasing or decreasing the polishing removal rate.

The water-soluble polymer includes polyvinyl alcohol (PVA), polyvinylpyrrolidone, polyethylene glycol (PEG), polypropylene glycol, polybutylene glycol, a copolymer of oxyethylene (EO) and oxypropylene (PO), methyl cellulose, hydroxyethyl cellulose, dextrin, pullulan, and the like. One type of these water-soluble polymers may be used alone or two or more types thereof may be used in combination. Among the water-soluble polymers, nonionic polymers are preferable from the viewpoint of preventing the inhibition of the effects of the surfactants on the surfaces of the abrasives and the TEOS (not varying the zeta potential).

The water-soluble polymer is not limited to the nonionic polymer. The water-soluble polymer may be cationic or anionic. The cationic polymer includes polyethyleneimine, polyvinylimidazole, polyallylamine, and the like. The anionic polymer includes polyacrylic acid, carboxymethyl cellulose, polyvinyl sulfonic acid, polyanetol sulfonic acid, polystyrene sulfonic acid, and the like.

PVA is preferably used as the water-soluble polymer because the polishing removal rate of the polysilicon can be increased. The average molecular weight of the PVA is 100 or more and 150000 or less, for example. From the viewpoint of ease of action on the hydrophobic film, the average molecular weight is preferably large. From the viewpoint of slurry dispersibility, the average molecular weight is preferably small. For example, from the viewpoint of ease of action on the hydrophobic film, the average molecular weight of the PVA is preferably 1000 or more, more preferably 3000 or more, still more preferably 6000 or more, and yet still more preferably 8000 or more. From the viewpoint of slurry dispersibility, the average molecular weight of the PVA is preferably 150000 or less, more preferably 100000 or less, still more preferably 80000 or less, yet still more preferably 40000 or less, even yet still more preferably 20000 or less, and even yet still more preferably 15000 or less.

PEG is preferably used as the water-soluble polymer because the polishing removal rate of the polysilicon can be lowered. The average molecular weight of the PEG is 200 or more and 150000 or less, for example. From the viewpoint of ease of action on the hydrophobic film, the average molecular weight is preferably large. From the viewpoint of slurry dispersibility, the average molecular weight is preferably small. For example, from the viewpoint of ease of action on the hydrophobic film, the average molecular weight of the PEG is preferably 1000 or more, more preferably 3000 or more, still more preferably 6000 or more, and yet still more preferably 8000 or more. From the viewpoint of slurry dispersibility, the average molecular weight of the PEG is preferably 150000 or less, more preferably 100000 or less, still more preferably 80000 or less, yet still more preferably 40000 or less, even yet still more preferably 20000 or less, and even yet still more preferably 15000 or less.

### <Oxidant>

The polishing composition according to the embodiment of the present invention may contain an oxidant. When the objects to be polished contain silicon, e.g., Poly-Si (polycrystalline silicon), the addition of the oxidant to the polishing composition enables the adjustment of the polishing removal rate. More specifically, by selecting the type of the oxidant to be added to the polishing composition, the polishing removal rate of the Poly-Si can be increased or reduced. Specific examples of the oxidant include hydrogen peroxide, peracetic acid, percarbonate, urea peroxide, perchloric acid, persulfate, and the like. Specific examples of persulfate include sodium persulfate, potassium persulfate, ammonium persulfate, and the like. One type of these oxidants may be used alone or two or more types thereof may be used in combination. Among these oxidants, persulfate and hydrogen peroxide are preferable and hydrogen peroxide is particularly preferable.

When the content of the oxidant in the entire polishing composition is higher, the polishing removal rate of the objects to be polished is more easily changed by the polishing composition. Hence, the content of the oxidant in the entire polishing composition is preferably 0.01% by mass or more, more preferably 0.05% by mass or more, and still more preferably 0.1% by mass or more. When the content of the oxidant in the entire polishing composition is lower, the material cost of the polishing composition can be further reduced. Further, a load of the disposal of the polishing composition after polishing, i.e., waste liquid disposal, can be reduced. In addition thereto, excessive oxidation of the surface of the objects to be polished by the oxidant is less likely to occur. Hence, the content of the oxidant in the entire polishing composition is preferably 10% by mass or less, more preferably 5% by mass or less, and still more preferably 3% by mass or less.

### <Antifungal Agent, Antiseptic Agent>

The polishing composition may contain an antifungal agent, an antiseptic agent. Specific examples of the antifungal agent, the antiseptic agent include isothiazolin-based antiseptic agents (e.g., 2-methyl-4-isothiazolin-3-one, 5-chloro-2-methyl-4-isothiazolin-3-one), paraoxybenzoic acid esters, and phenoxyethanol. One type of these antifungal agents, the antiseptic agents may be used alone or two or more types thereof may be used in combination.

### <Method for Manufacturing Polishing Composition>

A method for manufacturing the polishing composition of this embodiment is not particularly limited. The polishing composition can be manufactured by stirring and mixing the cationized colloidal silica chemically surface-modified with the amino silane coupling agent (i.e., amino group is immobilized on the surface), the anionic surfactant, the pH adjuster and, as necessary, various additives (e.g., water-soluble polymer, oxidant, complexing agent, antifungal agent, antiseptic agent, and the like) in a liquid medium, such as water. The temperature in the mixing is not particularly limited and is preferably 10° C. or more and 40° C. or lower, and may be increased to improve the dissolution rate. The mixing time is not particularly limited.

### <Objects to be Polished>

The polishing composition according to the embodiment of the present invention can improve the polishing removal rate of the TEOS film. Therefore, the object to be polished is preferably the TEOS film. However, the type of the objects to be polished is not limited to the TEOS and may be simple substance silicon, silicon compounds other than the TEOS, metal, and the like. The simple substance silicon includes single crystal silicon, polysilicon, amorphous silicon, and the like. The silicon compounds include silicon nitride, silicon dioxide, silicon carbide, and the like. A silicon compound film includes a low dielectric constant film having a relative dielectric constant of 3 or less. The metal includes tungsten, copper, aluminum, hafnium, cobalt, nickel, titanium, tantalum, gold, silver, platinum, palladium, rhodium, ruthenium, iridium, osmium, and the like. These metals may be contained in the form of an alloy or a metal compound.

### <Polishing Method>

The configuration of a polishing apparatus is not particularly limited, and, for example, a common polishing apparatus is usable which includes a holder holding a substrate having the object to be polished or the like, a drive unit, such as a motor, capable of changing the rotation speed, and a polishing platen to which a polishing pad (polishing cloth) can be stuck. As the polishing pad, common non-woven fabric, polyurethane, porous fluororesin, and the like can be used without particular limitation. As the polishing pad, one that has been grooved such that a liquid polishing composition can be collected is usable.

The polishing conditions are not particularly limited and, for example, the rotation speed of the polishing platen is preferably 10 rpm (0.17 s⁻¹) or more and 500 rpm (8.3 s⁻¹) or less. The pressure (polishing pressure) applied to the substrate having the object to be polished is preferably 0.5 psi (3.4 kPa) or more and 10 psi (68.9 kPa) or less. A method for supplying the polishing composition to the polishing pad is not particularly limited, and a method for continuously supplying the polishing composition with a pump or the like is adopted. The supply amount is not limited and is preferably such that the surface of the polishing pad is constantly covered with the polishing composition of one aspect of the present invention.

The polishing composition according to the embodiment of the present invention may be a one-component type or a multi-component type, such as a two-component type. The polishing composition may be prepared by diluting a liquid concentrate of the polishing composition with a diluting solution, such as water, 10-fold or more, for example.

After the polishing is completed, the substrate is cleaned with running water, for example, and then dried by wiping off water droplets adhering onto the substrate by a spin dryer or the like, thereby obtaining a substrate having a layer containing a silicon containing material, for example. As described above, the polishing composition according to the embodiment of the present invention can be used for an application to polish the substrate. By polishing the surface of the objects to be polished, such TEOS, provided on the semiconductor substrate using the polishing composition according to the embodiment of the present invention, the surface of the semiconductor substrate can be polished at a high polishing removal rate, thereby manufacturing a polished semiconductor substrate. The semiconductor substrate includes silicon wafers having a layer containing simple substance silicon, silicon compounds, metal, and the like.

### EXAMPLES

The present invention is described below in more detail with reference to Examples and Comparative Examples. However, the technical scope of the present invention is not limited to only Examples below. Examples below can be variously altered or modified and embodiments obtained by such alternations or modifications may also be included in the present invention.

### <Method for Preparing Polishing Composition>

### Examples 1 to 17

As shown in Table 1 below, abrasives, an anionic surfactant, and water, which is a liquid medium, were stirred and mixed, thereby preparing a mixed solution. A pH adjuster was added to the prepared mixed solution such that the pH was as shown in Table 1, thereby manufacturing polishing compositions of Examples 1 to 17. In Table 1, “-” indicates that components indicated by “-” were not used.

In Examples 1 to 17, for abrasives, cationized colloidal silica chemically surface-modified with aminopropyltriethoxysilane (APTES) as a coupling agent was used. The concentration of the coupling agent in the polishing composition was set to 0.1 mmol/L. Hereinafter, mol/L is indicated as M. The concentration of the abrasives in the polishing composition was set to 1% by mass in terms of silica.

Specifically, APTES was added to a liquid concentrate of colloidal silica (20% by mass) such that the concentration was 2 mM, thereby preparing surface-modified cationized colloidal silica. The APTES added to the liquid concentrate was diluted with abrasives such that the concentration was further reduced to 1/20 in preparing the polishing composition. Thus, the concentration of the APTES in the polishing composition was set to 0.1 mM in polishing. In the polishing composition, the APTES can be contained in a state of being bonded to the colloidal silica surface and a state of APTES as it was. The particle diameter (average secondary particle diameter) of the abrasives in the polishing composition is 70 nm. The zeta (ζ) potentials of the abrasives in the polishing compositions are as shown in Table 1.

In Examples 1 to 17, substances shown in Table 1 were used for the anionic surfactant. Functional groups of the anionic surfactants are a sulfate group in Example 1, sulfonic acid groups in Examples 2 to 12, and phosphate groups in Examples 13 to 17. The concentration of the surfactant in each polishing composition was set to 50 ppm in Examples 1 to 6, 8 to 19 and 100 ppm in Example 7.

In Example 5, PVA having an average molecular weight of 100 or more and 150000 or less was added as the water-soluble polymer. The addition amount of the PVA in the polishing composition was set to 50 ppm. In Example 6, PEG having an average molecular weight of 200 or more and 150000 or less was added as the water-soluble polymer. The addition amount of the PEG in the polishing composition was set to 50 ppm.

In Examples 1 to 17, nitric acid (HNO₃) or potassium hydroxide (KOH) was used as the pH adjuster. In Examples 1, 2, 5 to 17, the pH value of the polishing compositions was adjusted to 3.5. In Example 3, the pH value of the polishing composition was adjusted to 4.0. In Example 4, the pH value of the polishing composition was adjusted to 5.0. The pH of the polishing compositions (liquid temperature: 25° C.) was measured with a pH meter (product name: LAQUA (registered trademark) manufactured by HORIBA, Ltd.). The electrical conductivity (EC) values of the polishing compositions with the adjusted pH are as shown in Table 1.

### Comparative Examples 1 to 18

Each polishing composition was prepared in the same operation as in Examples 1 to 17, except that the pH of each polishing composition was adjusted to the value shown in Table 1 using each component of the type and with the concentration and the like shown in Table 1.

As a difference from Examples 1 to 17, in Comparative Examples 1, 2, the pH values of the polishing compositions were adjusted to 3.0, 6.0, respectively. In Comparative Examples 3 to 11, 13, 15, 17, 18, the anionic surfactant was not added. Na P-toluenesulfonate, Na p-styrenesulfonate, and o-cresol sulfonic acid in Comparative Examples 3 to 5, respectively, all have short carbon chains of hydrophobic groups and do not function as surfactants. In Comparative Examples 11 to 18, the surface modification of by the chemical treatment with the amino silane coupling agent was not applied to colloidal silica. Tetraethylammonium (TEAH) used in Comparative Examples 13 to 16 and tetrabutylammonium hydroxide (TBAH) used in Comparative Examples 17, 18 are all physically absorbed on the surface of colloidal silica but do not form a chemical bond.

TABLE 1

| | Abrasives | | | | | | |
|---|---|---|---|---|---|---|---|
| | Modification compound | | | | Particle | | |
| | | Coupling | Concentration | Concentration | diameter | ζ potential | Surfactant |
| | Compound | agent | (mM) | % by mass | nm | mV | Name |
| Ex. 1 | APTES | Coupling | 0.1 | 1 | 70 | 32.3 | Na dodecyl sulfate |
| | | agent | | | | | |
| Ex. 2 | APTES | Coupling | 0.1 | 1 | 70 | 34.0 | Na linear alkyl |
| | | agent | | | | | (C10-C16) |
| | | | | | | | benzene sulfonate |
| Ex. 3 | APTES | Coupling | 0.1 | 1 | 70 | 32.1 | Na linear alkyl |
| | | agent | | | | | (C10-C16) |
| | | | | | | | benzene sulfonate |
| Ex. 4 | APTES | Coupling | 0.1 | 1 | 70 | 10.1 | Na linear alkyl |
| | | agent | | | | | (C10-C16) |
| | | | | | | | benzene sulfonate |
| Ex. 5 | APTES | Coupling | 0.1 | 1 | 70 | 31.1 | Na linear alkyl |
| | | agent | | | | | (C10-C16) |
| | | | | | | | benzene sulfonate |
| Ex. 6 | APTES | Coupling | 0.1 | 1 | 70 | 32.6 | Na linear alkyl |
| | | agent | | | | | (C10-C16) |
| | | | | | | | benzene sulfonate |
| Ex. 7 | APTES | Coupling | 0.1 | 1 | 70 | 32.7 | Na linear alkyl |
| | | agent | | | | | (C10-C16) |
| | | | | | | | benzene sulfonate |
| Ex. 8 | APTES | Coupling | 0.1 | 1 | 70 | 38.4 | Hexadecylmethyl(3- |
| | | agent | | | | | sulfopropyl)hydroxide |
| | | | | | | | inner salt |
| Ex. 9 | APTES | Coupling | 0.1 | 1 | 70 | 30.9 | Na 1-dodecane |
| | | agent | | | | | sulfonate |
| Ex. 10 | APTES | Coupling | 0.1 | 1 | 70 | 30.5 | Na bis-(2-ethylhexyl) |
| | | agent | | | | | sulfosuccinate |
| Ex. 11 | APTES | Coupling | 0.1 | 1 | 70 | 33.5 | Branched chain |
| | | agent | | | | | alkylbenzene sulfonate |
| Ex. 12 | APTES | Coupling | 0.1 | 1 | 70 | 32.2 | Alkylnaphthalene |
| | | agent | | | | | sulfonate (butyl group) |
| Ex. 13 | APTES | Coupling | 0.1 | 1 | 70 | 36.1 | Polyoxyethylene alkyl |
| | | agent | | | | | phenyl ether phosphate |
| | | | | | | | amine salt |
| Ex. 14 | APTES | Coupling | 0.1 | 1 | 70 | 35.1 | Polyoxyethylene |
| | | agent | | | | | styrenated phenyl ether |
| | | | | | | | phosphoric acid ester |
| | | | | | | | and Polyoxyethylene |
| | | | | | | | styrenated phenyl ether |
| Ex. 15 | APTES | Coupling | 0.1 | 1 | 70 | 30.9 | Ethyl acid phosphate |
| | | agent | | | | | |
| Ex. 16 | APTES | Coupling | 0.1 | 1 | 70 | 31.1 | Butyl acid phosphate |
| | | agent | | | | | |
| Ex. 17 | APTES | Coupling | 0.1 | 1 | 70 | 32.1 | Bbutoxyethyl acid |
| | | agent | | | | | phosphate |
| Comp. | APTES | Coupling | 0.1 | 1 | 70 | 36.3 | Na linear alkyl |
| Ex. 1 | | agent | | | | | (C10-C16) |
| | | | | | | | benzene sulfonate |
| Comp. | APTES | Coupling | 0.1 | 1 | 70 | −3.2 | Na linear alkyl |
| Ex. 2 | | agent | | | | | (C10-C16) |
| | | | | | | | benzene sulfonate |
| Comp. | APTES | Coupling | 0.1 | 1 | 70 | 14.9 | Na p-toluenesulfonate |
| Ex. 3 | | agent | | | | | |
| Comp. | APTES | Coupling | 0.1 | 1 | 70 | 15.7 | Na p-styrenesulfonate |
| Ex. 4 | | agent | | | | | |
| Comp. | APTES | Coupling | 0.1 | 1 | 70 | 24.4 | o-cresol sulfonic acid |
| Ex. 5 | | agent | | | | | |
| Comp. | APTES | Coupling | 0.1 | 1 | 70 | 37.1 | — |
| Ex. 6 | | agent | | | | | |
| Comp. | APTES | Coupling | 0.1 | 1 | 70 | 37.8 | — |
| Ex. 7 | | agent | | | | | |
| Comp. | APTES | Coupling | 0.1 | 1 | 70 | 34.6 | — |
| Ex. 8 | | agent | | | | | |
| Comp. | APTES | Coupling | 0.1 | 1 | 70 | 10.8 | — |
| Ex. 9 | | agent | | | | | |
| Comp. | APTES | Coupling | 0.1 | 1 | 70 | −4.7 | — |
| Ex. 10 | | agent | | | | | |
| Comp. | — | | — | 1 | 70 | 6.7 | — |
| Ex. 11 | | | | | | | |
| Comp. | — | | — | 1 | 70 | 3.1 | Na linear alkyl |
| Ex. 12 | | | | | | | (C10-C16) |
| | | | | | | | benzene sulfonate |
| Comp. | TEAH | Adsorbent | 0.1 | 1 | 70 | 10.2 | — |
| Ex. 13 | | | | | | | |
| Comp. | TEAH | Adsorbent | 0.1 | 1 | 70 | 8.5 | Na linear alkyl |
| Ex. 14 | | | | | | | (C10-C16) |
| | | | | | | | benzene sulfonate |
| Comp. | TEAH | Adsorbent | 1 g/Kg | 1 | 70 | 28.1 | — |
| Ex. 15 | | | | | | | |
| Comp. | TEAH | Adsorbent | 1 g/Kg | 1 | 70 | — | Na linear alkyl |
| Ex. 16 | | | | | | | (C10-C16) |
| | | | | | | | benzene sulfonate |
| Comp. | TBAH | Adsorbent | 0.1 | 1 | 70 | 14.3 | — |
| Ex. 17 | | | | | | | |
| Comp. | TBAH | Adsorbent | 1 g/Kg | 1 | 70 | 27.2 | — |
| Ex. 18 | | | | | | | |

| | Surfactant | | Water-soluble polymer | | Physical property | |
|---|---|---|---|---|---|---|
| | Functional | Concentration | | Concentration | pH | EC |
| | group | [ppm] | Compound | [ppm] | [—] | [mS/cm] |
| Ex. 1 | —SO4 | 50 | — | — | 3.5 | 0.173 |
| Ex. 2 | —SO3 | 50 | — | — | 3.5 | 0.160 |
| Ex. 3 | —SO3 | 50 | — | — | 4.0 | 0.090 |
| Ex. 4 | —SO3 | 50 | — | — | 5.0 | 0.045 |
| Ex. 5 | —SO3 | 50 | PVA | 50 | 3.5 | 0.137 |
| Ex. 6 | —SO3 | 50 | PEG | 50 | 3.5 | 0.155 |
| Ex. 7 | —SO3 | 100 | — | — | 3.5 | 0.185 |
| Ex. 8 | —SO3 | 50 | — | — | 3.5 | 0.157 |
| Ex. 9 | —SO3 | 50 | — | — | 3.5 | 0.161 |
| Ex. 10 | —SO3 | 50 | — | — | 3.5 | 0.164 |
| Ex. 11 | —SO3 | 50 | — | — | 3.5 | 0.160 |
| Ex. 12 | —SO3 | 50 | — | — | 3.5 | 0.166 |
| Ex. 13 | —PO4 | 50 | — | — | 3.5 | 0.205 |
| Ex. 14 | —PO4 | 50 | — | — | 3.5 | 0.184 |
| Ex. 15 | —PO4 | 50 | — | — | 3.5 | 0.163 |
| Ex. 16 | —PO4 | 50 | — | — | 3.5 | 0.166 |
| Ex. 17 | —PO4 | 50 | — | — | 3.5 | 0.211 |
| Comp. | —SO3 | 50 | — | — | 3.0 | 0.570 |
| Ex. 1 | | | | | | |
| Comp. | —SO3 | 50 | — | — | 6.0 | 0.034 |
| Ex. 2 | | | | | | |
| Comp. | —SO3 | 5 mM | — | — | 3.5 | 0.592 |
| Ex. 3 | | | | | | |
| Comp. | —SO3 | 5 mM | — | — | 3.5 | 0.563 |
| Ex. 4 | | | | | | |
| Comp. | —SO3 | 5 mM | — | — | 3.5 | 0.509 |
| Ex. 5 | | | | | | |
| Comp. | — | — | — | — | 3.0 | 0.558 |
| Ex. 6 | | | | | | |
| Comp. | — | — | — | — | 3.5 | 0.197 |
| Ex. 7 | | | | | | |
| Comp. | — | — | — | — | 4.0 | 0.071 |
| Ex. 8 | | | | | | |
| Comp. | — | — | — | — | 5.0 | 0.024 |
| Ex. 9 | | | | | | |
| Comp. | — | — | — | — | 6.0 | 0.030 |
| Ex. 10 | | | | | | |
| Comp. | — | — | — | — | 3.5 | 0.164 |
| Ex. 11 | | | | | | |
| Comp. | — | 50 | — | — | 3.5 | 0.163 |
| Ex. 12 | | | | | | |
| Comp. | — | — | — | — | 3.5 | 0.160 |
| Ex. 13 | | | | | | |
| Comp. | — | 50 | — | — | 3.5 | 0.175 |
| Ex. 14 | | | | | | |
| Comp. | — | — | — | — | 3.5 | 0.803 |
| Ex. 15 | | | | | | |
| Comp. | — | 50 | — | — | 3.5 | 0.788 |
| Ex. 16 | | | | | | |
| Comp. | — | — | — | — | 3.5 | 0.164 |
| Ex. 17 | | | | | | |
| Comp. | — | — | — | — | 3.5 | 0.215 |
| Ex. 18 | | | | | | |

### <Evaluation>

Using the polishing compositions of Examples 1 to 17 and Comparative Examples 1 to 18, a silicon wafer having a diameter of 200 mm was polished under the following polishing conditions.

Polishing apparatus: One side CMP polishing apparatus for 200 mm wafer (Mirra manufactured by Applied Materials, Inc.)

Polishing pad: Rigid urethane pad IC1010 (manufactured by NITTAHAAS, Inc.)

Polishing pressure: 2 psi (1 psi=6894.76 Pa)

Rotational speed of polishing platen: 43 rpm

Rotational speed of head: 47 rpm

Supply of polishing composition: In one-way

Supply amount of polishing composition: 200 mL/min

Polishing time: 60 sec

The silicon wafers used for the polishing are a silicon wafer with a silicon dioxide film (TEOS film), a silicon wafer with a silicon nitride film (SiN film), and a silicon wafer with a polysilicon film (Poly-Si film). The silicon wafers were individually measured for the film thicknesses before and after the polishing using an optical interferometry film thickness meter. Then, the polishing removal rate of each film was calculated from the film thickness difference and the polishing time. The results are shown in Table 2.

TABLE 2

| | | | | Selection ratio | | |
|---|---|---|---|---|---|---|
| | Polishing removal rate | | | | TEOS/ | TEOS |
| | TEOS | SiN | Poly-Si | TEOS/SiN | Poly-Si | improvement |
| | [Å/min] | [Å/min] | [Å/min] | [—] | [—] | rate |
| Ex. 1 | 433 | 6 | — | 74.56 | — | 1.73 |
| Ex. 2 | 407 | 77 | 62 | 5.30 | 6.61 | 1.63 |
| Ex. 3 | 362 | 61 | — | 5.96 | — | 1.54 |
| Ex. 4 | 300 | 33 | — | 9.21 | — | 1.47 |
| Ex. 5 | 459 | 84 | 208 | 5.49 | 2.21 | 1.84 |
| Ex. 6 | 464 | 104 | 36 | 4.48 | 12.94 | 1.86 |
| Ex. 7 | 403 | 120 | — | 3.36 | — | 1.61 |
| Ex. 8 | 469 | 9 | — | 53.36 | — | 1.88 |
| Ex. 9 | 424 | 5 | — | 87.61 | — | 1.70 |
| Ex. 10 | 456 | 8 | — | 55.71 | — | 1.83 |
| Ex. 11 | 454 | 15 | — | 29.98 | — | 1.82 |
| Ex. 12 | 422 | 10 | — | 43.04 | — | 1.69 |
| Ex. 13 | 367 | 7 | — | 51.47 | — | 1.47 |
| Ex. 14 | 261 | 9 | — | 30.74 | — | 1.05 |
| Ex. 15 | 320 | 17 | — | 18.69 | — | 1.28 |
| Ex. 16 | 309 | 15 | — | 21.09 | — | 1.24 |
| Ex. 17 | 278 | 15 | — | 19.18 | — | 1.12 |
| Comp. Ex. 1 | 26 | 9 | — | 2.77 | — | 1.22 |
| Comp. Ex. 2 | 34 | 10 | — | 3.39 | — | 0.68 |
| Comp. Ex. 3 | 176 | 10 | — | 18.13 | — | 0.71 |
| Comp. Ex. 4 | 188 | 8 | — | 23.57 | — | 0.75 |
| Comp. Ex. 5 | 121 | 8 | — | 14.31 | — | 0.48 |
| Comp. Ex. 6 | 21 | 6 | — | 3.69 | — | — |
| Comp. Ex. 7 | 250 | 3 | — | 87.25 | — | — |
| Comp. Ex. 8 | 234 | 27 | — | 8.78 | — | — |
| Comp. Ex. 9 | 204 | 8 | — | 26.09 | — | — |
| Comp. Ex. 10 | 50 | 18 | — | 2.78 | — | — |
| Comp. Ex. 11 | 29 | 72 | — | 0.40 | — | — |
| Comp. Ex. 12 | 33 | 32 | — | 1.04 | — | — |
| Comp. Ex. 13 | 256 | 68 | — | 3.76 | — | — |
| Comp. Ex. 14 | 229 | 31 | — | 7.49 | — | 0.89 |
| Comp. Ex. 15 | 52 | 22 | — | 2.34 | — | — |
| Comp. Ex. 16 | Aggregated | — | — | — | — | — |
| Comp. Ex. 17 | — | — | — | — | — | — |
| Comp. Ex. 18 | — | — | — | — | — | — |

As shown in Table 2, the polishing removal rate of the TEOS film was 260 Å/min or more in all of Examples 1 to 17 and less than 260 Å/min in all of Comparative Examples 1 to 18. It was found that the polishing removal rate of the TEOS film was higher in Examples 1 to 16 than in Comparative Examples 1 to 18.

As described above, Examples are superior to Comparative Examples in terms of the polishing removal rate of the TEOS film. The improvement rate of the polishing removal rate of the TEOS film (hereinafter referred to as the TEOS improvement rate) was 1.05 or more in all of Examples 1 to 16. The TEOS improvement rate is the ratio of the polishing removal rate when the surfactant was added to the polishing composition to the polishing removal rate when the surfactant was not added at the same pH in each Example and each Comparative Example. More specifically, when the pH was 3.0, 3.5, 4.0, 5.0, and 6.0, the polishing removal rate ratio to Comparative Examples 6, 7, 8, 9, and 10, respectively, was defined as the TEOS improvement rate. A case where the TEOS improvement rate exceeded 1 means that the polishing removal rate is improved by adding the surfactant to the polishing composition. In all of Examples 1 to 16, the TEOS improvement rate was 1.05 or more, which showed that the polishing removal rate of the TEOS film was increased by using the anionic surfactant and the cationized colloidal silica chemically surface-modified with the amino silane coupling agent in combination.

The reason why the polishing removal rate of the TEOS film is increased is as follows. More specifically, when the anionic surfactant is adsorbed on the surface of the TEOS film, the surface of the TEOS film is anionized by a functional group. The zeta (ζ) potential of the cationized colloidal silica has a positive value under acidic conditions. Therefore, the colloidal silica as the abrasives is attracted to the TEOS film by electrostatic force under acidic conditions. This improves the polishing removal rate of the TEOS film.

As can be understood by comparing Examples 1 to 17 subjected to the chemical surface modification (chemical bond) and Comparative Examples 13 to 18 subjected to the physical adsorption, the zeta potential of the abrasives tends to be higher in the chemical surface modification (chemical bond) of the present invention than in the physical adsorption of Comparative Examples, when the pH values are the same. In the case of the physical adsorption, even when the anionic surfactant is added, the improvement effect of the polishing removal rate of the TEOS film cannot be obtained. Hence, it is found that the chemical surface modification of the present invention is likely to improve the polishing removal rate of the TEOS film. Further, in the case of the physical adsorption, if diluted, the zeta potential of the abrasives decreases due to a reduction in the adsorbent concentration. In contrast thereto, in the case of the chemical surface modification of the present invention, the amino group is immobilized on the surface of the abrasives, and therefore the zeta potential is less likely to vary due to dilution. More specifically, in the polishing composition of the present invention, the polishing removal rate is less likely to decrease even when diluted for use.

A comparison between Examples 1 to 17 (particularly Examples 2 to 4) and Comparative Examples 1, 2 showed that, when the pH value of the polishing composition was larger than 3 and smaller than 6, the polishing removal rate of the TEOS film was increased.

Further, it was found that, when the pH value was 3.5, the polishing removal rate of the TEOS film was higher in Examples 1, 2, 6 to 12 using the sulfonic acid-based surfactants than in Examples 13 to 17 using the phosphoric acid-based surfactants. It was found that the polishing removal rate of the TEOS film was further increased by using the sulfonic acid-based surfactants as the anionic surfactant.

Further, it was found that the polishing removal rate of the SiN film was higher in Examples 2 to 7 using the linear alkylbenzene sulfonates as the anionic surfactant than in the other Examples 1, 8 to 17 using the anionic surfactants other than the linear alkylbenzene sulfonate. It was found that the use of the linear alkylbenzene sulfonate as the anionic surfactant increased the polishing removal rate of not only the TEOS film but the SiN film.

When Examples 2, 5 are compared, the polishing removal rate of the Poly-Si film is higher in Example 5 than in Example 2. A difference between Examples 2, 5 is that the PVA is contained in the polishing compositions. This result showed that, by adding the PVA to the polishing composition according to the embodiment of the present invention, the polishing removal rate of the Poly-Si film was increased.

When Examples 2, 6 are compared, the polishing removal rate of the Poly-Si film is lower in Example 6 than in Example 2. A difference between Examples 2, 6 is that the PEG is contained in the polishing composition. This result showed that, by adding the PEG to the polishing composition according to the embodiment of the present invention, the polishing removal rate of the Poly-Si film was lowered.

Examples 2, 5, 6 showed that, by selectively adding the PVA, the PEG to the polishing composition according to the embodiment of the present invention, the controllability of the polishing removal rate of the Poly-Si film was also able to be improved while improving the polishing removal rate of the TEOS film.

1. A polishing composition comprising:
cationized colloidal silica chemically surface-modified with an amino silane coupling agent; and
an anionic surfactant, wherein
a pH value is larger than 3 and smaller than 6.

2. The polishing composition according to claim 1, wherein the amino silane coupling agent includes aminotrialkoxysilane.

3. The polishing composition according to claim 1, wherein the amino silane coupling agent includes aminopropyltriethoxysilane.

4. The polishing composition according to claim 1, wherein a zeta potential of the cationized colloidal silica is 30 mV or more.

5. The polishing composition according to claim 1, wherein the anionic surfactant includes an organic acid salt having one or more functional groups selected from a sulfate group, a sulfonic acid group, and a phosphoric acid group.

6. The polishing composition according to claim 1, wherein the anionic surfactant includes linear alkylbenzene sulfonate.

7. The polishing composition according to claim 1, further comprising:
a water-soluble polymer.

8. The polishing composition according to claim 7, wherein the water-soluble polymer includes polyvinyl alcohol having an average molecular weight of 100 or more and 150000 or less.

9. The polishing composition according to claim 7, wherein the water-soluble polymer includes polyethylene glycol having an average molecular weight of 200 or more and 150000 or less.

10. A method for manufacturing the polishing composition according to claim 1, the method comprising:
mixing cationized colloidal silica chemically surface-modified with an amino silane coupling agent, an anionic surfactant, and a pH adjuster in a liquid medium.

11. A polishing method comprising:
polishing an object to be polished provided on a substrate using the polishing composition according to claim 1, wherein
the object to be polished includes silicon dioxide.

12. The polishing composition according to claim 2, wherein the amino silane coupling agent includes aminopropyltriethoxysilane.

13. The polishing composition according to claim 2, wherein a zeta potential of the cationized colloidal silica is 30 mV or more.

14. The polishing composition according to claim 3, wherein a zeta potential of the cationized colloidal silica is 30 mV or more.

15. The polishing composition according to claim 2, wherein the anionic surfactant includes an organic acid salt having one or more functional groups selected from a sulfate group, a sulfonic acid group, and a phosphoric acid group.

16. The polishing composition according to claim 3, wherein the anionic surfactant includes an organic acid salt having one or more functional groups selected from a sulfate group, a sulfonic acid group, and a phosphoric acid group.

17. The polishing composition according to claim 4, wherein the anionic surfactant includes an organic acid salt having one or more functional groups selected from a sulfate group, a sulfonic acid group, and a phosphoric acid group.

18. The polishing composition according to claim 2, wherein the anionic surfactant includes linear alkylbenzene sulfonate.

19. The polishing composition according to claim 3, wherein the anionic surfactant includes linear alkylbenzene sulfonate.

20. The polishing composition according to claim 4, wherein the anionic surfactant includes linear alkylbenzene sulfonate.
